(19) United States
(12) Patent Application Publication
(10) Pub. No.: US 2026/0054287 A1
(43) Pub. Date: Feb. 26, 2026

(54) PASSIVATION COATING ON COPPER METAL SURFACE FOR COPPER WIRE BONDING APPLICATION

(71) Applicant: University of North Texas, Denton, TX (US)

(72) Inventors: Oliver Ming-Ren Chyan, Denton, TX (US); John Faruk Alptekin, Denton, TX (US); Goutham Issac Ashok Kumar, Denton, TX (US)

(21) Appl. No.: 18/867,790

(22) PCT Filed: May 15, 2023
(86) PCT No.: PCT/IB2023/054990

§ 371 Date: Nov. 20, 2024

Related U.S. Application Data
(60) Provisional application No. 63/345,868, filed on May 25, 2022.

(51) Int. Cl. H01L 23/00; B05D 1/00; B05D 1/18; B05D 3/10; C23G 1/10; H01L 23/495

(52) U.S. Cl. CPC H01L 24/43; B05D 1/18; B05D 1/60; B05D 3/102; C23G 1/103; H01L 23/4952; H01L 24/05; H01L 24/08; H01L 24/45; H01L 24/48; H01L 24/73; B05D 2202/25; B05D 2202/45; B05D 2401/10; H01L 2224/04042; H01L 2224/05007; H01L 2224/05124; H01L 2224/05147; H01L 2224/08501; H01L 2224/43001; H01L 2224/431; H01L 2224/43985; H01L 2224/45147; H01L 2224/45565; H01L 2224/48177; H01L 2224/48647; H01L 2224/73207; H01L 2924/365

(57) ABSTRACT

The invention provides improved techniques for bonding devices using copper-to-copper or other types of bonds. A substrate is cleaned to remove surface oxides and contaminants and then rinsed. The rinsed substrate is provided to coating unit where a protective coating is applied to the substrate. The protective coating may be applied by immersing the substrate in a bath or via chemical vapor deposition. In an aspect, the protective coating may be copper selective so that the protective coating is only applied to copper features of the substrate. The protective coating minimizes formation of oxides and other bond weakening forces that may form during bonding processes, such as bonding a copper wire to a copper bond pad of the substrate. In an aspect, an annealing process is used to cure the protective coating and remove small imperfections and other abnormalities in the protective coating prior to the bonding process.

### CROSS-REFERENCE TO RELATED APPLICATION

The present application claims priority to U.S. Provisional Application No. 63/345,868 filed May 25, 2022 and entitled “PASSIVATION COATING ON COPPER METAL SURFACE FOR COPPER WIRE BONDING APPLICATION,” the disclosure of which is incorporated by reference herein in its entirety.

### TECHNICAL FIELD

The present disclosure generally relates to bi-metallic devices, and more particularly to techniques for reducing formation of bond-weakening forces in copper wire bonding applications.

### BACKGROUND OF THE INVENTION

Copper (Cu) being the fifth most abundant material in earth's crust, is one of the most commonly used metals among a wide spectrum of industrial applications. For example, copper is frequently used in wires, metal sheets, heat exchanger parts, electrical and electronic applications, marine industries, as well as many other industrial applications. Copper has rapidly replaced gold (Au) as the preferred wire-bonding material in microelectronic packaging due to its higher electrical conductivity, lower cost, and better mechanical strength, which leads to reduced pad size and pad pitch. However, corrosion-related failures need to be minimized to ensure packaging reliability. As an example, Aluminum (Al) bond pads are particularly susceptible to corrosion with a characteristic “mud-crack” appearance. Such corrosion can lead to critical failure of Cu wire-bonded assemblies, especially under harsh conditions such as automotive environments. The emerging trend of wearable electronics also imposes new, more stringent packaging reliability requirements to ensure corrosion protection from sweat/mud/rain in all-terrain, non-stop usage conditions.

The corrosion problem is exacerbated when bonding two dissimilar metals (e.g., Al bond pads connected to Cu wires, etc.) due to the galvanic contact which provides a thermodynamic driving force for accelerated Al corrosion, which can lead to a weak bond and result in separation of the Cu wires from the Al bond pads or other failures. For example and referring to FIG. 1, a block diagram illustrating aspects of a bonding process in accordance with the prior art is shown. As shown in FIG. 1, a Cu wire 102 may be bonded to a Al substrate 104 (e.g., a plate, a bond pad, etc.). To facilitate bonding of the Cu wire 102 to the Al substrate 104 heat may be introduced. To illustrate, a common bonding process may involve temperatures in the range of 195° C. to 205° C. (e.g., approximately 200° C.). At such temperatures the Cu wire 102 and the Al substrate 104 will directly connect, with some intermetallic compounds forming in between. If it is desired to eliminate this bimetallic contact, the Al substrate may be replaced with Cu or Cu containing alloys. In this case, at approximately 200° C. wirebonding temperature, the Cu may experience rapid oxidation, resulting in non-stick on the pad at the bond site 106. When such oxidation occurs during the bonding process the Cu-to-Cu bond between the Cu wire 102 and the Cu substrate 104 is weakened, thereby increasing the likelihood that the bond fails (i.e., resulting in separation of the Cu wire 102 from the Cu substrate 104), or does not even form a connection at all. Further details regarding the failure of Cu-to-Cu bonds according to the process shown in FIG. 1 are described in detail below.

The Cu oxidation problem and Al bond pad corrosion problem described above represent two technical challenges that remain unsolved and present a reliability issue for next generation packaging applications involving semiconductor devices. For example, next generation of automotive chips require very low defect rates approaching 0 parts per billion (ppb). Due to the above-described Cu-Al bimetallic corrosion and Cu oxidation issues that arise during the bonding process, the ability to realize such low defect rates when using Cu-to-Al and non-assisted Cu-to-Cu direct bonding is not feasible. Furthermore, current Cu wire bonding to Al bond pad packaging can suffer low ppm defects (e.g., multiple-lifting ball defects) that are still 1000% more than acceptable limits. Moreover, the defects with Cu-to-Al bonds often occur as the result of tough to track causes, making attempts to mitigate such defects challenging.

### BRIEF SUMMARY OF THE INVENTION

The present invention provides techniques for minimizing defects (e.g., corrosion, oxidation, etc.) in wire bonding applications involving Cu wires. Non-limiting examples of Cu wire bonding applications to which the disclosed techniques may be applied include Cu-Al wire bonding applications, Cu-Cu wire bonding applications, and Cu lead frame applications. The disclosed bonding techniques enable Cu-to-Al bonds and Cu-to-Cu bonds to be realized in electrical devices while mitigating the problems associated with corrosion and oxidation described above. According to aspects of the present disclosure, a substrate (e.g., Cu and Cu alloys) and Cu-to-Al bonded assembly may be cleaned (e.g., using a mildly acidic solution or dry etching technique) to remove surface oxides and contaminants.

Once cleaned, the substrate may be rinsed (e.g., using water) and then provided to a coating unit where a protective coating is applied to the substrate. The protective coating may be applied by immersing the substrate in a bath or via chemical vapor deposition. In an aspect, the protective coating may be copper selective so that the protective coating only adheres to or primarily adheres to copper features of the substrate, such as copper bond pads. The protective or passivating coating may minimize the development of corrosion defects that arise during bonding of Cu wires, such as may occur during bonding processes involving Cu-to-Al bonding devices. In another aspect, the protective coating may minimize formation of oxides and other bond weakening forces that may form during storage and especially during bonding processes, such as bonding of a Cu wire to a Cu bond pad of the substrate, as a non-limiting example. Eliminating or minimizing the extreme oxidation that occurs during bonding of Cu wires may significantly improve the quality of the bond between the two Cu features (e.g., Cu wires and bond pads, lead frames, etc.) and may improve the reliability of the resulting bonded device(s). For example, the obstacle to achieving Cu-Cu bonding is the ambient and thermal-driven oxidation of Cu, which can generate oxides greater than 100 nm thick. This oxide layer prevents the joining of two Cu interfaces. By depositing a removable and ultrathin passivating film to protect the Cu surface from oxidation, the substrate may be maintained in a clean and oxide-free state for subsequent bonding to the next copper feature. In an aspect, an annealing process may be used to cure the protective coating and remove small imperfections and other abnormalities in the protective coating prior to the bonding process. It is also noted that the passivation coating can also be used to protect other types of devices, such as Cu lead frames, from oxidation and facilitate the bonding of Cu wires without a costly Ag coating layer.

Using the techniques disclosed herein may facilitate reliable manufacturing of next generation packaging technology for automotive applications that require more robust, corrosion resistance and high conductivity connections (e.g., to reach required AEC grade 1, 0 safety standards). Thus, the techniques disclosed herein may improve the reliability of Cu-Al wire bonded devices (e.g., by mitigating or minimizing formation of corrosion at the Cu-Al bond-site) and facilitate the highest bonding reliability for direct Cu-Cu wire bonding applications (e.g., by mitigating or minimizing corrosion at the Cu-Cu bond-site).

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawing, in which:

FIG. 1 shows a block diagram illustrating aspects of a bonding process in accordance with the prior art;

FIGS. 2A-2D show block diagrams illustrating techniques for preventing non-stick on a pad for Cu wire bonds in accordance with aspects of the present disclosure;

FIG. 3 shows a block diagram illustrating an exemplary system for producing devices having metallic bonds in accordance with aspects of the present disclosure;

FIG. 4 shows an image of a Cu surface having a protective coating applied in accordance with the present disclosure;

FIG. 5 shows a diagram illustrating oxide suppression in accordance with aspects of the present disclosure;

FIG. 6 shows a diagram illustrating reliability of bonds between Cu wires and Al substrates;

FIG. 7 shows a diagram illustrating reliability of bonds between Cu wires and Cu substrates,

FIGS. 8A-8C show a block diagram and images illustrating exemplary aspects for performing bonding of Cu wires to a lead frame in accordance with aspects of the present disclosure; and

FIG. 9 shows a flow diagram of an exemplary method for performing bonding of Cu devices in accordance with aspects of the present disclosure.

It should be understood that the drawings are not necessarily to scale and that the disclosed embodiments are sometimes illustrated diagrammatically and in partial views. In certain instances, details which are not necessary for an understanding of the disclosed methods and apparatuses or which render other details difficult to perceive may have been omitted. It should be understood, of course, that this disclosure is not limited to the particular embodiments illustrated herein.

### DETAILED DESCRIPTION OF THE INVENTION

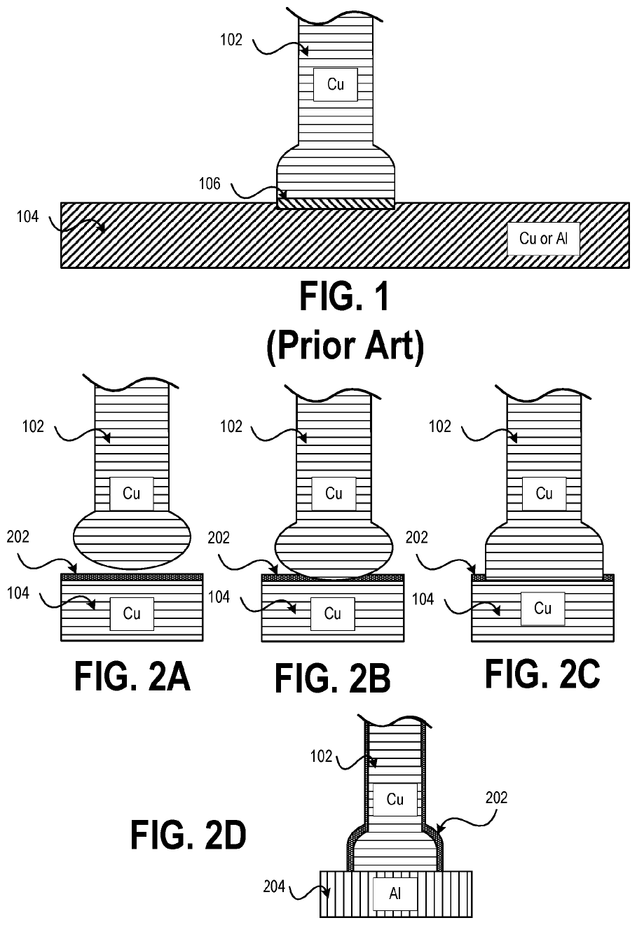

Referring to FIGS. 2A-2D, a block diagrams illustrating techniques for bonding Cu wires in accordance with aspects of the present disclosure is shown. In FIGS. 2A-2C, the Cu wire 102 and the Cu substrate 104 are shown. The Cu wire 102 may be one of a variety of bonding wires containing Cu metal. For example, the Cu wire 102 may include Cu wires, wires formed of Cu alloys, and metal-coated Cu wire (like palladium coated Cu (PCC). Cu substrate 104 represents a substrate having Cu features corresponding to metallic structures to which Cu wires may be bonded in accordance with the present disclosure. The Cu features may include, for example, metal bonding pads to which Cu wires may be bonded. It is noted that the Cu features may include Cu features (e.g., Cu bond pads) and features formed from Cu alloys (e.g., Cu alloy bond pads), as non-limiting examples. As compared to FIG. 1, in one aspect, the Cu substrate 104 in FIGS. 2A-2C has been coated with a protective coating 202 in accordance with concepts disclosed herein. The protective coating 202 may protect the Cu substrate 104 prior to initiating the bonding process. As shown in FIG. 2B, during bonding the Cu wire 102 may be pressed into and through the coating 202, thereby making contact with the Cu substrate 104. During the bonding process the presence of the protective coating 202 minimizes the development of oxidation between the Cu wire 102 and the Cu substrate 104, thereby improving the strength of the bond formed between the Cu wire 102 and the Cu substrate 104.

In FIG. 2D the substrate 104 of FIGS. 2A-2C is replaced with a substrate 204, which can be a substrate including Al bonding pads. As described above, when bonding the Cu wire 102 to the Al substrate 204 (e.g., an Al bonding pad) is performed according to prior techniques the resulting Cu-Al bimetallic contacts can cause galvanic corrosion and lead to corrosion defect failures. To mitigate such corrosion defects and failures and as shown in FIG. 2D, a Cu wire may be bonded on an Al bond pad can be coated with the protective coating 202 in accordance with concepts disclosed herein. The protective coating 202 may be used to passivate the Cu bonding wire 102 and terminate the source of Cu-Al bimetallic contact, which may eliminate failures caused by corrosion defects.

It is to be appreciated that advantages provided by aspects of the present disclosure are not realized solely based on the presence of the protective coating 202 of FIGS. 2A-2D. Instead, the present disclosure provides innovative techniques to apply the protective coating 202 to metallic devices and eliminate defects present in the protective coating 202. Thus, it is to be appreciated that the disclosed Cu wire bonding techniques, whether involving Cu-to-Cu bonded devices (e.g., Cu, Cu alloys, coated Cu, or combinations thereof) or Cu-to-Al bonded devices, improve the manner in which the protective coating 202 is applied to the metallic devices in addition to enhancing the ability to mitigate corrosion and oxidation during the bonding process, as described in more detail below.

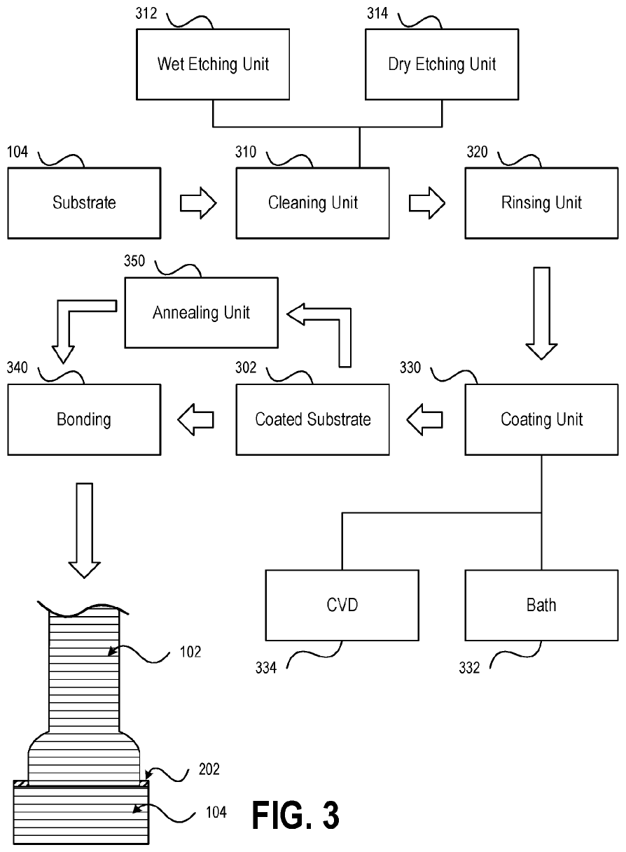

Referring to FIG. 3, a block diagram illustrating an exemplary system for producing devices having metallic bonds in accordance with aspects of the present disclosure is shown. It is noted that FIG. 3 is described below with reference to Cu wire bonding applications involving a substrate. However, it should be understood that the concepts illustrated and described with reference to FIG. 3 may be performed with respect to metallic devices involving other forms of Cu wire bonding applications. For example, the processes described with reference to FIG. 3 as being applied to the substrate may also be applied to Cu wire bonded semiconductor devices (e.g., in applications involving application of a protective or passivating coating to Cu wires that have been bonded to a substrate having Al bond pads, as in FIG. 2D), or other types of metallic devices (e.g., lead frames, etc.).

As shown in FIG. 3, the system may include a cleaning unit 310, a rinsing unit 320, a coating unit 330, and a bonding unit 340. The cleaning unit 310 may be configured to enable cleaning of a substrate, such as the substrate 104 of FIGS. 2A-2C. The cleaning unit 310 may include a wet etch unit 312, a dry etch unit 314, or both. The wet etch unit 312 may include a container, such as a plastic or glass container, that may be filled with a cleaning solution and the substrate may be placed in the cleaning solution. While immersed in the cleaning solution bath, any contaminants and oxides present on the surface of the substrate may be removed by the cleaning solution. For example, the cleaning solution may be an acid and the substrate may be placed in the acid bath for a period of time to clean the surface of the substrate. In an aspect, the period of time in which the substrate is placed in the cleaning solution bath may be approximately 1 minute. In additional or alternative aspects the period of time may be longer or short than 1 minute (e.g., 30 seconds(s), 40 s, 45 s, 50 s, 55 s, 30-55 s, 55 s to 65 s, 65-85 s, 70 s, 80 s, 90 s, etc.). In an aspect, the acid used as the cleaning solution may be 3.5% sulfuric acid. In additional or alternative aspects other formulations of sulfuric acid or another type of acid (e.g., acetic acid, hydrochloric acid, citric acid, other mild forms of acids, etc.) or cleaning solution may be utilized by the wet etch unit 312. The dry etch unit 314 may include an etching device configured to clean the surface of the metallic device(s) without the use of a cleaning solution, as is used by the wet etch unit 312. For example, the dry etch unit 314 may include a plasma etcher employing Ar, H₂, N₂, O₂, or mixtures thereof. The plasma etcher may treat the surface of the substrate (or other metallic device, or Cu wire bonded semiconductor devices) with plasma, thereby removing surface contaminants and oxides from the substrate. It is noted that plasma etching has been described herein for purposes of illustration, rather than by way of limitation and the other techniques may be used by the dry etch unit 314 if desired (e.g., laser etching, etc.).

Once cleaned, the substrate may be provided to the rinsing unit 320. The rinsing unit 320 may be configured to rinse the cleaning solution off of the substrate. The rinsing may be performed using deionized water or another rinsing agent. After rinsing is complete, the substrate may be provided to the coating unit 330 where a protective coating is applied to the substrate. As shown at in FIG. 3, the protective coating may be applied by the coating unit 330 in a variety of ways, including via a bath, shown in FIG. 3 as bath coating unit 332, or via chemical vapor deposition (CVD), shown in FIG. 3 as CVD coating unit 334. The bath coating unit 332 may include a container (e.g., a glass or plastic container) and the protective coating may be applied by immersing the (cleaned and rinsed) substrate within a non-aqueous liquid bath. The non-aqueous liquid bath may include a solvent and one or more inhibitor compounds (i.e., the material providing the protective coating). The solvent may include ethanol, isopropanol, acetone, hexane, other solvents, or mixtures thereof (e.g., water and ethanol; water and isopropanol; acetone and hexane; water, acetone, and hexane; and so on). The one or more inhibitor compounds may be 5-mercapto-1-phenyl-tetrazole, 5-(4-methoxyphenyl)-2-amino1,3,4-thiadiazole, sulfathiazole, 5-amino1,3,4-thiadiazol 2-thiol, 1-phenyl-1H-tetrazole-5-thiol, 2-(2-dihydroxy-5-methyl)-phenyl-benzotriazole, 5-methyl-benzotriazole, amino tertiary butyl pyrazole, tetrazole, dodecane thiol, azimino toluene, 1,2,4-triazole, cyproconazole, 4-(2-aminothiazol-4-yl)-phenol, 5-methyl-2-phenyl-2,4-dihydropyrazol-3-one, phenyl isothiocyanate; 4-methyl-5-imidazolecarbaldehyde, 5-(3-aminophenyl)-tetrazole, 2-amino-4-(4-chlorophenyl)-thiazol, 1-H-benzotriazole, 2-mercapto-benzoxazole, 5-methyl-benzotriazole, 5-methyl-benzimidazole, 2-mercapto benzimidazole, pyrazole, toly-triazole, 4-methyl-5-hydroxymethylimidazole, diniconazole, 4-(4-aminostyryl)-N,N-dimethylaniline, 8-methyl-benzotriazole, 3,5-diamino-1,2,4-triazole, phenyl urea, 5-(4-methoxyphenyl)-2-amino1,3,4-thiadiazole,5-mercapto-1-phenyl-tetrazole, phenyl methyl benzotriazole, benzoxazole, other azole-based compounds, additional types of (non-azole compounds) compounds, or combinations thereof. In an aspect, the inhibitor compound(s) may be Cu selective such that when the substrate is immersed in the non-aqueous liquid bath provided by the bath coating unit 332, the inhibitor compound forms the protective coating on Cu components of the immersed substrate, such as Cu bonding pads, circuitry, wires, etc., and not to other portions of the substrate (e.g., a silicon wafer, ceramic substrate, a substrate formed form organic materials, and the like). In an alternative aspect, the bath used to apply the coating may utilize water (i.e., an aqueous bath), alone or in combination with other solvents (e.g., water and ethanol; water and isopropanol; water and acetone; water and hexane; water, acetone, and hexane; and so on). In an aspect, the bath may be heated. For example, the bath may be heated to a temperature in the range of 15° C. to 105° C. In some aspects, the bath may be heated to a temperature between 20° C. to 100° C., 25° C. to 100° C., 25° C. to 95° C., 30° C. to 90° C., 35° C. to 85° C., 35° C. to 90° C., 40° C. to 100° C., 40° C. to 90° C., or another within the range of 20° C. to 100° C. In some aspects, the bath may be heated to a temperature of approximately 70° C. In some aspects, the bath may be heated to a temperature between 50° C. to 90° C., 55° C. to 85° C., 60° C. to 80° C., 65° C. to 75° C., 68° C. to 72° C., 70° C. to 90° C., or 60° C. to 90° C. In some aspects, the bath may be mechanically stirred or agitated, such as by ultrasonic vibration, as a non-limiting example.

The CVD coating unit 334 may include a CVD chamber in which the substrate may be placed during application of the protective coating. To apply the protective coating the CVD chamber may be heated after the substrate is disposed therein and vapors of the one or more inhibitor compounds may be introduced into the CVD chamber. Alternatively, a quantity of the one or more inhibitor compounds may be placed in the CVD chamber with the substrate during the heating and as the heating occurs, the one or more inhibitor compounds may be vaporized, thereby releasing vaporized molecules of the one or more inhibitor compounds within the CVD chamber. In an aspect, the heating of the CVD chamber may be performed at temperatures in the range of 80° C. to 200° C. In an aspect, the heating of the CVD chamber may be performed at temperatures between approximately 90° C. and 110° C. The vaporized inhibitor compound may deposit on the surface of the substrate, thereby forming the protective coating or passivation layer on the substrate. In embodiments utilizing the CVD coating unit 334, the inhibitor compound may be the same inhibitor compound(s) described above with reference to the bath coating unit 332. Furthermore, the inhibitor compound may be Cu selective, thereby ensuring that the protective coating obtained through the CVD coating unit 334 is provided on Cu components (e.g., Cu bond pads, circuitry, wires, lead frame, etc.) rather than other portions of the substrate (e.g., a silicon wafer, etc.).

In an aspect, the temperature used to heat the CVD chamber may be configured to control characteristics of the protective coating being applied, properties or characteristics of the metallic device being coated (e.g., a Cu wire, a substrate having Cu bond pads, a lead frame, etc.). For example, certain temperatures may promote formation of ultrathin protective coatings while other temperatures may promote formation of thicker protective coatings. As another example, the metallic device placed within the CVD chamber may be heated during the heating of the CVD chamber, which may alter properties or characteristics of the surface of the metallic device (e.g., heating at certain temperatures may promote or cause oxidation of Cu metallic devices, such as Cu wires or bond pads). As such, the heating of the CVD chamber may be controlled to mitigate the occurrence of undesirable changes in the properties or characteristics of the metallic device(s) and to promote formation of a protective coating of a desired thickness.

In an aspect, the coated substrate may be rinsed following immersion in the bath coating unit 332 or deposition via the CVD coating unit 334. Rinsing the coated substrate may remove excess inhibitor compound(s) from the surface of the substrate. In an aspect, the rinsing may be performed using the same or a similar solvent to the solvents described above with reference to the bath coating unit 332.

As a result of the operations of the coating unit 330 (e.g., the bath coating unit 332 or the CVD coating unit 332) a protective coating may be deposited on the substrate to produce a coated substrate 302 (e.g., the substrate 104 and protective coating 202 of FIGS. 2A-2C or the wire 102 and protective coating 202 of FIG. 2D). The protective coating may have a thickness of between 1 nanometer (nm) to 200 nm. In an aspect, the protective coating may have a thickness between 1 nm and 20 nm, 10 nm and 50 nm, 25 nm to 75 nm, 50 nm to 100 nm, 75 nm to 125 nm, 100 nm to 150 nm, 125 nm to 175 nm 150 nm to 200 nm, or combinations thereof. It is noted that the various exemplary thickness ranges described above have been provided for purposes of illustration, rather than by way of limitation. As described above, the system of FIG. 3 provides functionality that may enable the thickness of the protective coating to be controlled, allowing thicker protective coatings or thinner protective coatings to be produced depending on the particular Cu bonding application involved and whether the particular Cu bonding application would benefit from a particular thickness of the protective coating.

As described above, when a Cu-selective inhibitor compound(s) is utilized the protective coating may be provided on Cu features of the substrate (e.g., bond pads, circuitry, wires, lead frame, etc.) while non-Cu portions of the substrate (e.g., silicon) may be unaffected by the protective coating. Utilizing the above-described techniques (e.g., the bath or CVD) to apply the one or more inhibitor compounds and form the protective coating is advantageous as compared to other possible application techniques. For example, it is possible to brush or roll on protective coatings, but the brushing technique results in the protective coating being deposited on the entire surface of the substrate, rather than just the Cu components or structures. Additionally, the brush or roll-on application methods also tend to lead to a non-uniform coating (e.g., in terms of thickness). In contrast, the bath and CVD methods disclosed herein can provide conformal coating around various complicated geometries, with potentially only 5-10% thickness variation. An additional advantage provided the bath method described above with reference to bath unit 332 is the use of non-aqueous solvents, which eliminates potential for the final product to have residual moisture trapped upon the packaging. However, as noted above, aqueous bath solutions may also be used to apply the one or more inhibitor compounds in some implementations.

After the coated Cu substrate 302 is produced it may be provided to a bonding unit 340. The bonding unit 340 may be configured to perform bonding of two or more Cu devices, such as bonding of Cu wires to Cu bonding pads on the coated substrate 302. As described above with reference to FIGS. 2A-2C, the Cu-to-Cu direct bonding enabled by protective coatings applied in accordance with the above-described features of the system of FIG. 3 may minimize or mitigate bimetallic corrosion and inter-metallics formation at the bonding site, thereby yielding a better bond (e.g., better electrical conductivity and bond strength) between the two Cu devices (e.g., Cu, Cu alloy, or coated Cu devices). As described in more detail below, bonding processes performed in accordance with the concepts described with reference to the system of FIG. 3 result in greater success in Cu-to-Cu bonding, thereby enabling next generation chips and devices satisfying ppb failure requirements to be realized. Similarly, the bonding processes also result in greater success in Cu-to-Al bonding.

In some aspects, the system 300 may include an annealing unit 350. The annealing unit 350 may be configured to anneal the coated substrate 302. For example, the annealing unit 350 may heat the coated substrate 302 to a desired temperature (e.g., a temperature between 100-260° C.). The annealing may be performed in a desired environment, such as air (e.g., either convection-style or static over), under vacuum (e.g., 1×10⁻⁹ Torr to 1 Torr), or under an inert gas (e.g., nitrogen, argon, forming gas— 95/5 nitrogen-hydrogen mixture), as non-limiting examples. The annealing of the coated substrate 302 may remove minor imperfections or other defects in the applied coating, thereby improving the protection against oxidation and degradation of the bonds formed during bonding at the bonding unit 340.

In an aspect, substrates and other metallic devices (e.g., wires, lead frames, etc.) processed using the system 300 may be maintained in a “wet” state prior to applying the protective coating at the coating unit 330. To maintain the substrates in the “wet” state prior to coating, the substrate(s) 104 may be placed in a container of water following cleaning via the cleaning unit 310 and transported to the rinsing unit 320 in the container of water. Once rinsed, the substrate may be placed in the same or new (clean) container of water for transport to the coating unit 330. At the coating unit 330, the cleaned and rinsed substrate may be removed and provided to the coating unit 310 for coating (e.g., via bath coating unit 332 or CVD coating unit 334), as described above. In an additional or alternative aspect, the substrate may be misted with water during transport between the cleaning unit 310, the rinsing unit 320, and the coating unit 330, rather than being placed in a water bath. Maintaining the substrate in the “wet” state subsequent to cleaning and prior to application of the protective coating may minimize the development of surface oxides or other contaminants on the substrate and may improve the adhesion or deposition of the protective coating to the Cu components of the substrate.

Using the processes described above with reference to the system 300 of FIG. 3 enables Cu-to-Cu bonds to be formed in a reliable manner since the inhibitor compound(s) used to provide the protective coating eliminates oxidation at the bonding site(s) (or corrosion at the bonding site for Cu-to-Al bonds). Moreover, since the inhibitor compound(s) may be Cu-selective, the substrate is not coated with excess material, minimizing the impact of the protective coating on the substrate or other components and features. The disclosed techniques also provide a low cost and fast coating process that is compatible with wafer fab Cu CMP processing. For example, the disclosed coating process can be performed at a cost of less than $15 per wafer. The disclosed coating process also minimizes or eliminates wafer warpage that may be caused by other coating techniques. Moreover, the coating process enhances packaging reliability and enables more reliable use of Cu-to-Cu bonded devices, which is more desirable form of bonded device as compared to Cu-to-Al bonded devices.

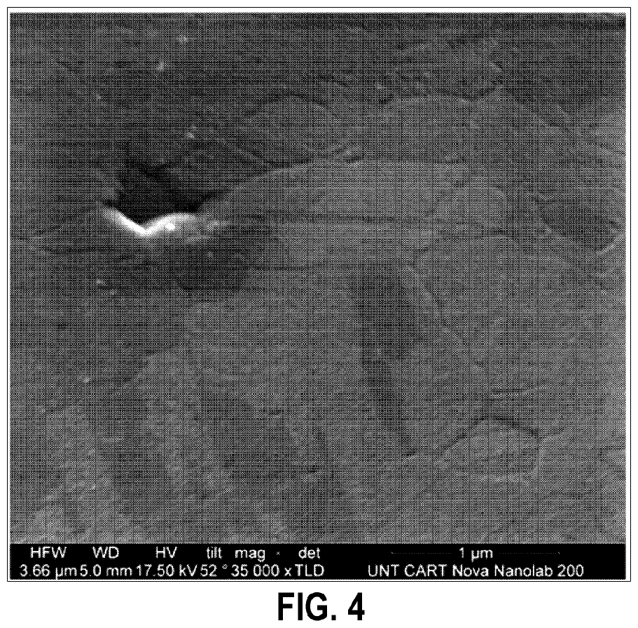

Referring to FIG. 4, an image of a Cu surface having a protective coating applied in accordance with the present disclosure is shown. As can be seen in the (scanning electron microscope (SEM)) image of FIG. 4, the passivated Cu surface shows visible grain structures, which indicates that the protective coating is conformal over the Cu surface. Thus, FIG. 4 illustrates that the coating techniques disclosed herein provide a uniform application of the protective coating (e.g., the one or more inhibitor compounds) on Cu surfaces.

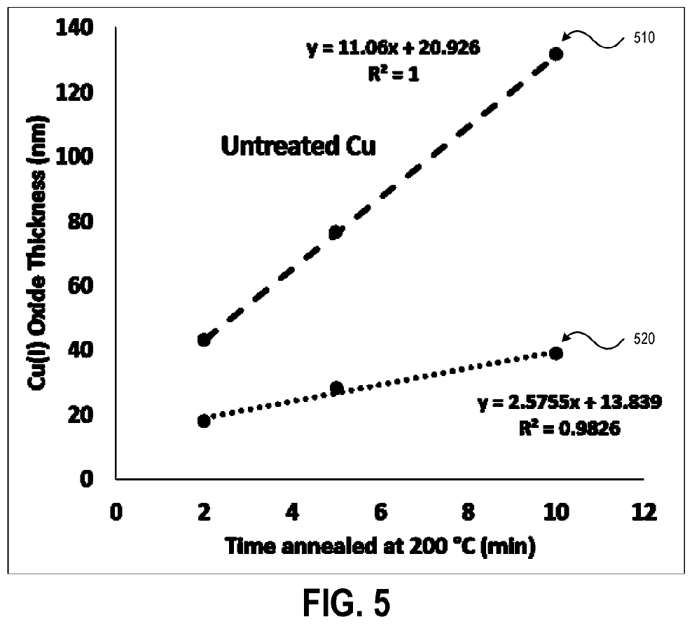

Referring to FIG. 5, a diagram illustrating oxide suppression in accordance with aspects of the present disclosure is shown. In the diagram of FIG. 5, a trendline 510 and a trendline 520 are shown. The trendline 510 represents oxidation of untreated Cu while the trendline 520 represents oxidation of Cu treated with a protective coating in accordance with the concepts disclosed herein. The protective coating associated with the Cu represented by the trendline 510 was approximately 11 nm thick. In the example of FIG. 5, data used to calculate the trendlines 510 was obtained by annealing the unprotected Cu corresponding to trendline 510 and the protected Cu corresponding to the trendline 520 at 200° C., which simulates temperatures common to bonding processes used for bonding Cu wires and devices. As can be observed in FIG. 5, the protective coating suppressed oxidation by 77% as compared to oxidation the unprotected Cu represented by the trendline 510.

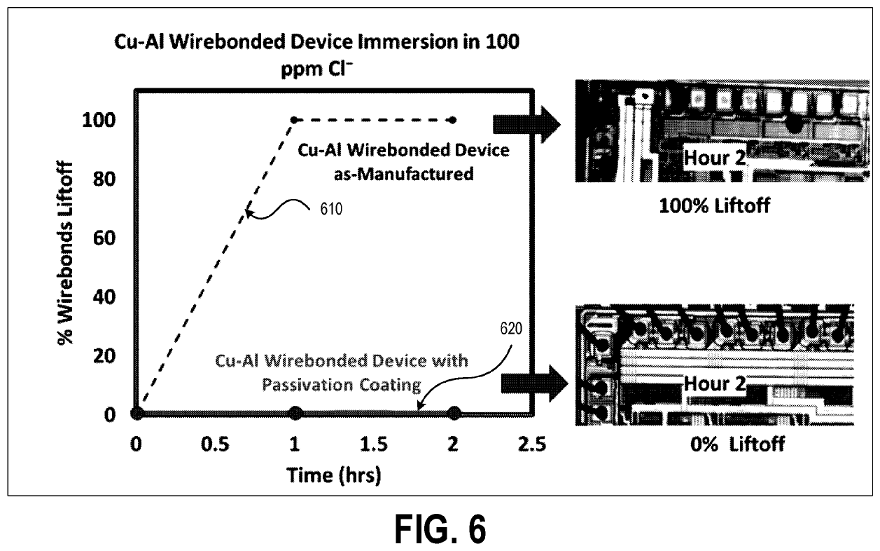

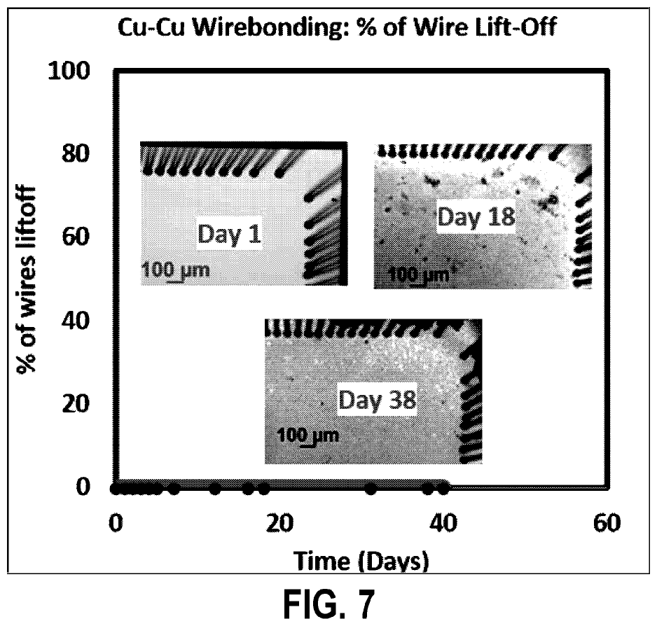

Referring to FIGS. 6 and 7, diagrams illustrating reliability of bonds between wires and devices are shown. In FIG. 6, a diagram illustrating testing of wire lift-off caused by corrosion for Cu wires bonded to Al bond pads is shown, and in FIG. 7 a diagram illustrating testing of wire lift-off for Cu wires bonded to Cu bond pads is shown. As seen in FIG. 6, at 610, within approximately 1 hour 100 % of the Cu wires had lifted off their Al bond pads, while there was no Cu wire lift off from the same type of Cu-to-Al bonded device protected by the passivation coating applied in accordance with concepts disclosed herein, as shown at 620. In FIG. 7, the Cu-to-Cu wire bonds, enabled by the passivation coating on the Cu bond pad, remain intact after 38 days. These corrosion screening results were obtained by placing the bonded devices in an acidic chloride solution (e.g., approximately 100 ppm Cl⁻ having a pH of 5) and observing the bonds with a microscope. Images captured periodically with the microscope were used to count the number of wire bonds that had lifted off or broken. As shown in FIG. 6, passivation coating on Cu-to-Al wire bonded devices can greatly suppress the corrosion induced Cu wire lift off defects. In addition, as can be seen in comparing the results of FIGS. 6 and 7, the replacement of Al bond pads with Cu bond pads passivated by this invention, as described above with reference to FIG. 3, significantly improved the lifespan of the Cu-to-Cu wire bonds (FIG. 7) as compared to the bonds that were not formed in accordance with the concepts disclosed herein (plot 710 of FIG. 6). The results shown in FIGS. 6 and 7 demonstrate that the replacement of Al with Cu and techniques for enabling the direct Cu-to-Cu bonding disclosed herein significantly improve the reliability of Cu-bonded devices, which may enable next generation automotive chips and other applications of bonded devices having high standards for reliability and low failure rates to be realized.

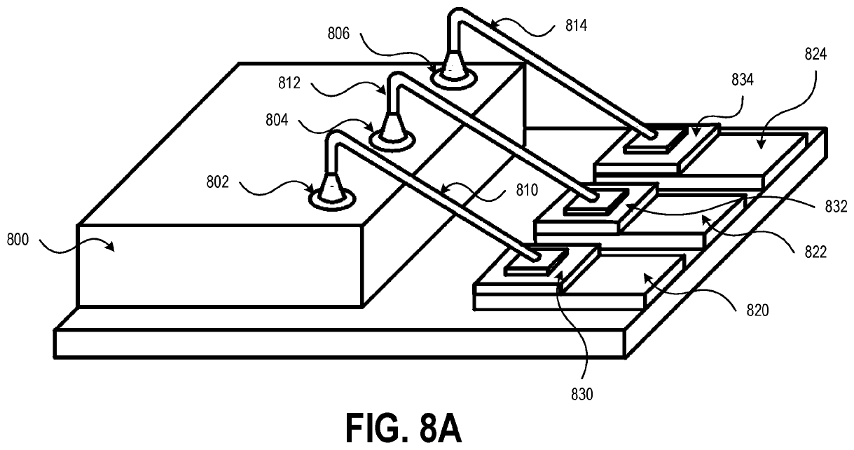

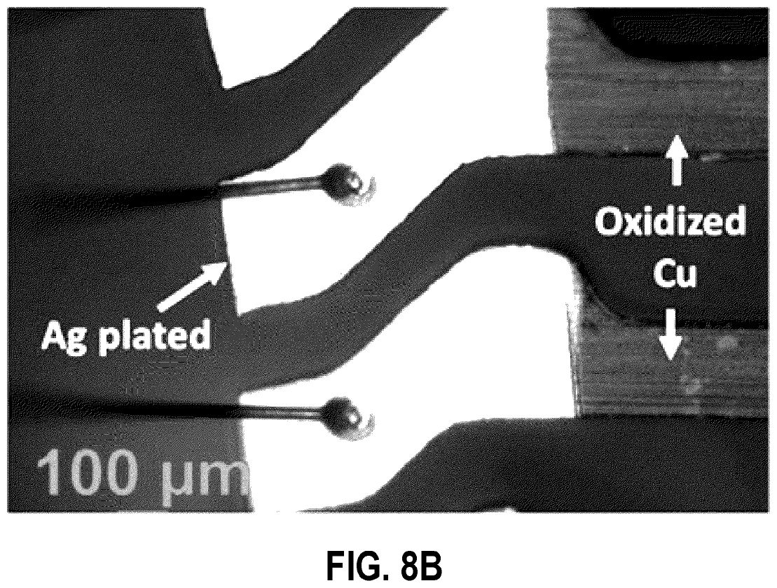

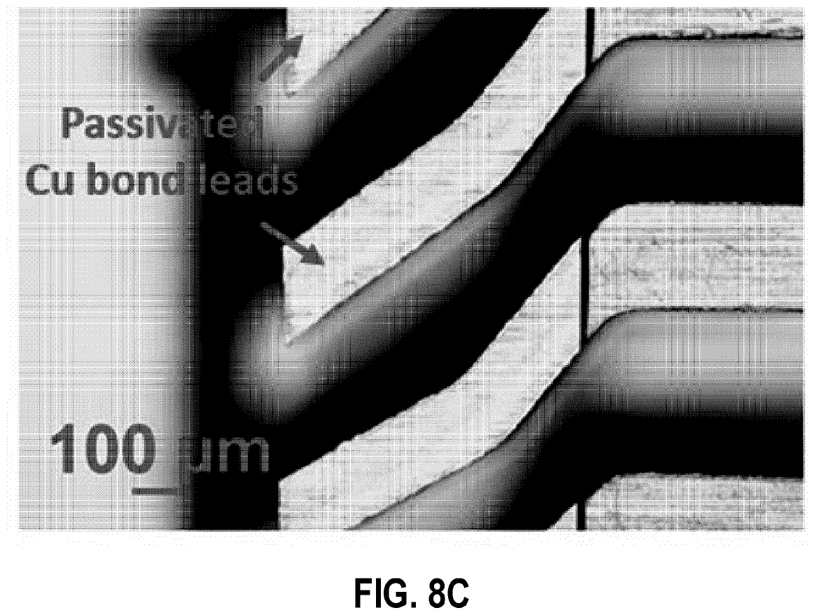

Referring to FIG. 8A, a block diagram illustrating additional exemplary Cu wire bonding applications in accordance with the present disclosure is shown. As described, and illustrated above with reference to FIGS. 2A-7, aspects of the present disclosure may facilitate various Cu wire bonding applications, such as bonding of Cu wires to metallic features of a substrate or chip (e.g., Cu bond pads, Al bond pads, etc.), in a manner that prevents oxidation, corrosion, or other forces that may weaken the bonds. FIG. 8A illustrates an additional application to which the protective coating techniques for performing bonding of Cu wires to metallic features may be applied, namely, lead frames. To illustrate, wires bonded to bond pads may carry the signals of an integrated circuit on a die to the outside world, but a lead frame is used to receive the other end of the Cu wire bonded to the die's bonding pads.

As an illustrative example, FIG. 8A shows an integrated circuit chip 800 having bond pads 802, 804, 806 (e.g., Cu or Al bond pads) having Cu wires 810, 812, 814 bonded thereto in accordance with the present disclosure, as described above with reference to FIGS. 2A-3. Lead frame components 820, 822, 824 are shown having lead frame bond pads 830, 832, 834. Prior to the present disclosure, when lead frame components 820, 822, 824 included Cu bond pads 830, 832, 834, the Cu bond pads of the lead frame components required silver (Ag) plating to prevent oxidation of the Cu lead frame components or bond pads (FIG. 8A), which increased the cost and complexity of manufacturing. However, using embodiments of the present disclosure, the Cu lead frame bond pads 830, 832, 834 may be treated with a protective coating using the techniques described above with reference to FIGS. 2A-3 to prevent oxidation of the Cu lead frame components or bond pads, as shown in FIG. 8B. As explained above, because a Cu selective passivating or protective coating is used, the protective coating applied using the techniques disclosed herein may be applied to the Cu portions of the lead frame (e.g., the Cu lead frame components 820, 822, 824 and the Cu lead frame bond pads 830, 832, 834) but not to other portions of the lead frame. Moreover, the protective coating may prevent oxidation during bonding of the Cu wires 810, 812, 814 to the Cu lead frame bond pads 830, 832, 834, resulting in a better connection between the integrated circuit and the lead frame, thereby improving the reliability (e. g, by minimizing lift off of the Cu wires due to oxidation, corrosion, etc.).

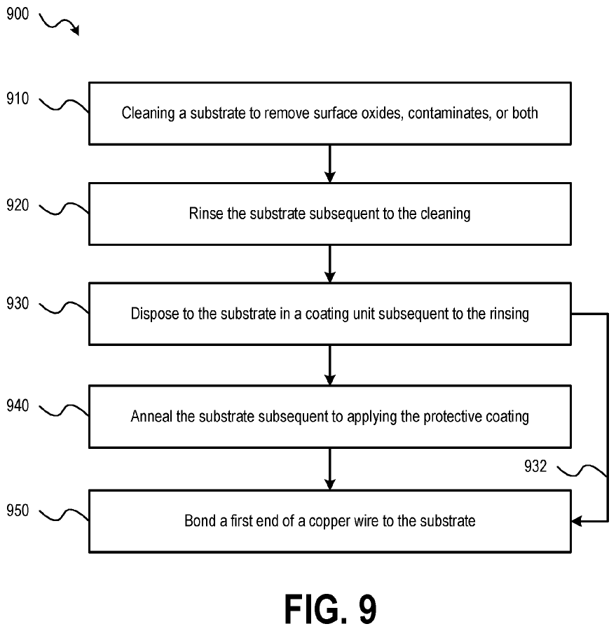

Referring to FIG. 9, a flow diagram of an exemplary method for performing bonding of Cu devices in accordance with aspects of the present disclosure is shown as a method 900. In an aspect, the method 900 may be performed using a system, such as the system 300 of FIG. 3. At step 910, the method 900 includes cleaning a substrate to remove surface oxides, contaminates, or both. As described above with reference to FIG. 3, the cleaning may be performed by immersing the substrate (or Cu wires, a lead frame, Cu wire bonded semiconductor devices, or other metallic structures) in a cleaning solution maintained in a container of a cleaning unit (e.g., the wet etch unit 312 of FIG. 3). The cleaning solution may include an acid, such as acidic solutions formed using sulfuric acid, acetic acid, HCl, citric acid, or other mildly acidic solutions. As described above, the cleaning may be performed by immersing the substrate in the cleaning solution for a period of time (e.g., approximately 1 minute). Alternatively, the cleaning may be performed in the absence of a cleaning solution, such as by the dry etch unit of FIG. 3. For example, the substrate (or Cu wires, the lead frame, Cu wire bonded semiconductor devices, or other metallic structures) may be treated by a plasma etcher or another form of “dry” etching to remove surface oxides, contaminates, etc. At step 920, the method 900 includes rinsing the substrate subsequent to the cleaning. In an aspect, the rinsing may be performed using a rinsing unit (e.g., the rinsing unit 320 of FIG. 3) and the rinsing of the substrate may utilize water to remove any cleaning solution or particles removed by the dry etching that remain present on the substrate after the cleaning.

At step 930, the method 900 includes disposing to the substrate in a coating unit subsequent to the rinsing. As described above with reference to FIG. 3, the coating unit (e.g., the coating unit 330 of FIG. 3) may be configured to apply a protective coating to at least a portion of the substrate. For example, the protective coating may be Cu selective such that the portion of the substrate covered by the protective coating corresponds to at least one or more copper features of the substrate, such as bond pads or other copper features. The protective coating applied to the substrate at step 930 may include one or more inhibitor compounds, such as 5-mercapto-1-phenyl-tetrazole, 5-(4-methoxyphenyl)-2-amino1,3,4-thiadiazole, sulfathiazole, 5-amino1,3,4-thiadiazol 2-thiol, 1-phenyl-1H-tetrazole-5-thiol, 2-(2-dihydroxy-5-methyl)-phenyl-benzotriazole, 5-methyl-benzotriazole, amino tertiary butyl pyrazole, tetrazole, dodecane thiol, azimino toluene, 1,2,4-triazole, cyproconazole, 4-(2-aminothiazol-4-y1)-phenol, 5-methyl-2-phenyl-2,4-dihydropyrazol-3-one, phenyl isothiocyanate; 4-methyl-5-imidazolecarbaldehyde, 5-(3-aminophenyl)-tetrazole, 2-amino-4-(4-chlorophenyl)-thiazol, 1-H-benzotriazole, 2-mercapto-benzoxazole, 5-methyl-benzotriazole, 5-methyl-benzimidazole, 2-mercapto benzimidazole, pyrazole, toly-triazole, 4-methyl-5-hydroxymethylimidazole, diniconazole, 4-(4-aminostyryl)-N,N-dimethylaniline, 8-methyl-benzotriazole, 3,5-diamino-1,2,4-triazole, phenyl urea, 5-(4-methoxyphenyl)-2-aminol3,4-thiadiazole, 5-mercapto-1-phenyl-tetrazole, phenyl methyl benzotriazole, benzoxazole, other azole-based and non-azole-based compounds, or combinations thereof. As described above with reference to FIG. 3, the protective coating may be copper-selective such that the coating adheres to the one or more copper features of the substrate and any portions of the protective coating not adhered to the copper feature(s) may be removed. For example, in an aspect, the substrate may be rinsed a second time following application of the protective coating to remove excess coating material (e.g., the inhibitor compounds described above with reference to FIG. 3). As described above with reference to FIG. 3, the coating unit may be a bath coating unit (e.g., the bath coating unit 332 of FIG. 3) or a CVD coating unit (e.g., the CVD coating unit 334 of FIG. 3). In some aspects the substrate may be maintained in a wet state in between steps 910, 920, 930, as described above with reference to FIG. 3.

At step 940, the method 900 includes annealing the substrate subsequent to applying the protective coating. As described above, annealing may mitigate or remove minor imperfections in the protective coating after its application. As indicated by arrow 932, in some aspects step 940 may be omitted. In an aspect, the substrate is maintained in a storage facility for a period of time prior to the bonding. By using the protective coating one or more copper features of the substrate may be prevented from developing oxides or other negative artifacts that may reduce the quality of subsequent bonding processes, thereby improving the quality of any subsequently formed bonds. At step 950, the method 900 includes bonding a first end of a copper wire to the substrate. As described above with reference to FIG. 8A, the first end of the copper wire may be bonded to a metallic structure or feature of an integrated circuit, such as a bond pad (e.g., a Cu or Al bond pad) of integrated circuit 800 of FIG. 8A. Subsequently, a second end of the copper wire may be bonded to a metallic structure of another substrate or device, such as a bond pad of a lead frame. It is noted that one or more steps of the method 900 may be performed multiple times, such as the bonding step, during which copper wires may be bonded to a plurality of metallic structures or features of a first device and/or a second device (e.g., bond pads of an integrated circuit or chip and a lead frame). It is further noted that while primarily described with reference to bonding of Cu wires to integrated circuits, chips, lead frames, and other semi-conductor devices, the techniques disclosed herein may be readily applied to any use case involving bonding of Cu wires and for which mitigation of oxidation during the Cu wire bonding process is desirable.

As described above with reference to FIGS. 6 and 7, the bonding performed at step 950 may be structurally improved as compared to other bonding processes, especially for Cu-to-Cu bonds. For example, the bonds formed at step 950 may exhibit improved strength (i.e., be less likely to break or for bonded wires to lift off their respective bonding pads). Such structural resiliency may improve the lifespan of devices and reduce failure rates, thereby enabling the benefits of Cu-to-Cu bonds to be utilized in certain environments, such as automotive applications, where bonded devices may be subject to harsh environments or corrosive forces. In addition to improving device reliability and safety, using the method 900 and system 300 also removes common corrosion concerns due to inter-metallics and galvanic contact associated with common Cu-Al and Cu-Sn connections. Moreover, the method 900 may be applied to wire bonding applications involving or Cu wire bonded semiconductor devices, such as the application of passivating or protective coatings to Cu wires that have been bonded to Al bond pads, as in FIG. 2D. As shown above, the method 900 and system 300 provide a chemistry-driven approach to selectively protect Cu features from oxidation via a wide selection of processes. Such capabilities enable low temperature vapor phase application of protective coatings for dry processes (e.g. for IC chip designs having features that can be damaged from liquid immersion). Additionally, unlike volatile corrosion inhibitors, the inhibitor compound(s) used to apply protective coatings in accordance with the concepts disclosed herein remain intact and bonded on Cu surfaces even in ambient conditions, making it ideal for situations where the substrates may require storage prior to performing bonding processes. Additionally, the techniques disclosed herein may also enable selective control of coating thickness, such as by changing process conditions (e.g., exposure time, temperature, concentration of inhibitor compounds, etc.).

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

Moreover, the scope of the present application is not intended to be limited to the particular embodiments of the process, machine, manufacture, composition of matter, means, methods and steps described in the specification.

1. A method comprising:
immersing a substrate in a cleaning solution to remove surface oxides, contaminates, or both;
rinsing the substrate to remove excess cleaning solution;
disposing the substrate in a coating unit subsequent to the rinsing, wherein the coating unit is configured to apply a protective coating to at least a portion of the substrate;
annealing the substrate subsequent to applying the protective coating; and
bonding a first end of a copper wire to the substrate.

2. The method of claim 1, wherein the cleaning solution comprises an acid.

3. The method of claim 1, wherein the coating unit comprises a bath coating unit, wherein the protective coating is applied by immersing the substrate in a solution comprising a solvent and one or more inhibitor compounds, and wherein the protective coating is formed from the one or more inhibitor compounds.

4. The method of claim 3, further comprising rinsing the substrate prior to the annealing and prior to the bonding.

5. The method of claim 1, wherein the coating unit comprises a chemical vapor deposition (CVD) coating unit having a CVD chamber, wherein the protective coating is applied by placing the substrate in the CVD chamber and heating one or more inhibitor compounds, wherein the heating is configured to vaporize the one or more inhibitor compounds, and wherein the protective coating is formed from deposition of the vaporized one or more inhibitor compounds on the surface of the substrate.

6. The method of claim 1, wherein the protective coating comprises one or more inhibitor compounds, and wherein the one or more inhibitor compounds comprise 5-mercapto-1-phenyl-tetrazole, 5-(4-methoxyphenyl)-2-aminol3,4-thiadiazole, sulfathiazole, 5-aminol3,4-thiadiazol 2-thiol, 1-phenyl-1H-tetrazole-5-thiol, 2-(2-dihydroxy-5-methyl)-phenyl-benzotriazole, 5-methyl-benzotriazole, amino tertiary butyl pyrazole, tetrazole, dodecane thiol, azimino toluene, 1,2,4-triazole, cyproconazole, 4-(2-aminothiazol-4-yl)-phenol, 5-methyl-2-phenyl-2,4-dihydropyrazol-3-one, phenyl isothiocyanate; 4-methyl-5-imidazolecarbaldehyde, 5-(3-aminophenyl)-tetrazole, 2-amino-4-(4-chlorophenyl)-thiazol, 1-H-benzotriazole, 2-mercapto-benzoxazole, 5-methyl-benzotriazole, 5-methyl-benzimidazole, 2-mercapto benzimidazole, pyrazole, toly-triazole, 4-methyl-5-hydroxymethylimidazole, diniconazole, 4-(4-aminostyryl)-N,N-dimethylaniline, 8-methyl-benzotriazole, 3,5-diamino-1,2,4-triazole, phenyl urea, 5-(4-methoxyphenyl)-2-aminol3,4-thiadiazole, 5-mercapto-1-phenyl-tetrazole, phenyl methyl benzotriazole, benzoxazole, other azole- and non-azole-based compounds, or combinations thereof.

7. The method of claim 1, wherein the protective coating is copper-selective.

8. The method of claim 1, wherein the substrate is maintained in a wet state in between the cleaning, the rinsing, and the applying the protective coating.

9. The method of claim 1, wherein the substrate is maintained in a storage facility for a period of time prior to the bonding.

10. The method of claim 1, wherein the first end of the copper wire is pressed into a portion of the protective coating applied to the substrate prior to the bonding.

11. A system comprising:
a cleaning unit configured to clean one or more metallic structures prior to initiating a bonding process involving the one or more metallic structures;
a rinsing unit configured to rinse the one or more metallic structures subsequent to cleaning of the one or more metallic structures by the cleaning unit;
a coating unit configured to apply a protective coating to at least a portion of the one or more metallic structures;
a bonding unit configured to bond a first end of a copper wire to a first metallic structure of the one or more metallic structures subsequent to applying the protective coating; and
at least one wetting means configured to maintain the one or more metallic structures in a wet state between the cleaning and the rinsing and between the rinsing and the coating.

12. The system of claim 11, wherein the coating unit comprises a bath coating unit comprising a solution comprising a solvent and one or more inhibitor compounds, and wherein the protective coating is applied by immersing the one or more metallic structures in the solution.

13. The system of claim 12, wherein the protective coating is formed from the one or more inhibitor compounds, and wherein at least one of the one or more inhibitor compounds is copper selective.

14. The system of claim 11, further comprising an annealing unit configured to anneal the one or more metallic structures subsequent to applying the protective coating and prior to the bonding.

15. The system of claim 11, wherein the cleaning unit comprises a wet etching unit, a dry etching unit, or both.

16. The system of claim 11, wherein the coating unit comprises a chemical vapor deposition (CVD) coating unit having a CVD chamber, wherein the protective coating is applied by placing the one or more metallic structures in the CVD chamber and heating one or more inhibitor compounds, wherein the one or more inhibitor compounds are vaporized by the heating, and wherein the protective coating is formed from deposition of the vaporized one or more inhibitor compounds on a surface of the copper wire, the one or more metallic structures, or both.

17. The system of claim 11, wherein the one or more metallic structures comprise copper bond pads, aluminum bond pads, a lead frame, copper wires, or combinations thereof.

18. The system of claim 11, wherein the protective coating is copper-selective.

19. The system of claim 11, wherein the one or more metallic structures is maintained in a storage facility for a period of time prior to the bonding.

20. The system of claim 11, wherein the one or more metallic structures comprise at least one of copper, copper alloys, plated copper, or combinations thereof.

21. The system of claim 11, wherein the bonding unit is configured to bond a second end of the copper wire to a second metallic structure of the one or more metallic structures, wherein the first metallic structure comprises a bond pad of an integrated circuit device, and the second metallic structure comprises a lead frame bond pad.

22. A method comprising:
cleaning one or more metallic features to remove surface oxides, contaminates, or both from the surface of the one or more metallic features;
rinsing the substrate to remove residual artifacts remaining after the cleaning;
bonding a first end of a copper wire to a first metallic feature of the one or more metallic features to produce a copper wire bonded device;
disposing the copper wire bonded device in a coating unit subsequent to the bonding, wherein the coating unit is configured to apply a protective coating to at least a portion of the copper wire bonded device.

23. The method of claim 22, further comprising annealing the copper wire bonded device subsequent to applying the protective coating.

24. The method of claim 22, wherein the cleaning comprises disposing the one or more metallic features in a bath solution comprises an acid.

25. The method of claim 22, wherein the coating unit comprises a bath coating unit, wherein the protective coating is applied to the copper wire bonded device by immersing the copper wire bonded device in a solution comprising a solvent and one or more inhibitor compounds, and wherein the protective coating is formed from at least one of the one or more inhibitor compounds.

26. The method of claim 22, wherein the coating unit comprises a chemical vapor deposition (CVD) coating unit having a CVD chamber, wherein the protective coating is applied by placing the one or more metallic structures in the CVD chamber and heating one or more inhibitor compounds, wherein the heating is configured to vaporize the one or more inhibitor compounds, and wherein the protective coating is formed from deposition of the vaporized one or more inhibitor compounds on the surface of the one or more copper features.

27. The method of claim 22, wherein the protective coating comprises one or more inhibitor compounds, wherein the one or more inhibitor compounds comprise 5-mercapto-1-phenyl-tetrazole, 5-(4-methoxyphenyl)-2-aminol3,4-thiadiazole, sulfathiazole, 5-aminol3,4-thiadiazol 2-thiol, 1-phenyl-1H-tetrazole-5-thiol, 2-(2-dihydroxy-5-methyl)-phenyl-benzotriazole, 5-methyl-benzotriazole, amino tertiary butyl pyrazole, tetrazole, dodecane thiol, azimino toluene, 1,2,4-triazole, cyproconazole, 4-(2-aminothiazol-4-yl)-phenol, 5-methyl-2-phenyl-2,4-dihydropyrazol-3-one, phenyl isothiocyanate; 4-methyl-5-imidazolecarbaldehyde, 5-(3-aminophenyl)-tetrazole, 2-amino-4-(4-chlorophenyl)-thiazol, 1-H-benzotriazole, 2-mercapto-benzoxazole, 5-methyl-benzotriazole, 5-methyl-benzimidazole, 2-mercapto benzimidazole, pyrazole, toly-triazole, 4-methyl-5-hydroxymethylimidazole, diniconazole, 4-(4-aminostyryl)-N,N-dimethylaniline, 8-methyl-benzotriazole, 3,5-diamino-1,2,4-triazole, phenyl urea, 5-(4-methoxyphenyl)-2-aminol3,4-thiadiazole, 5-mercapto-1-phenyl-tetrazole, phenyl methyl benzotriazole, benzoxazole, other azole- and non-azole-based compounds, or combinations thereof.

28. The method of claim 22, wherein the protective coating is copper-selective.

29. The method of claim 22, wherein the one or more metallic features are maintained in a wet state in between the cleaning, the rinsing, and the disposing the copper wire bonded device in the coating unit.

30. A system comprising:
a cleaning unit configured to clean one or more metallic structures;
a rinsing unit configured to rinse the one or more metallic structures subsequent to cleaning;
a bonding unit configured to bond a first end of a copper wire to a first metallic structure of the one or more metallic structures subsequent to the cleaning and the rinsing;
a coating unit configured to apply a protective coating to the one or more metallic structures prior to the bonding, the first end of the copper wire bonded to the first metallic structure subsequent to the bonding, or both; and
at least one wetting means configured to maintain the one or more metallic structures in a wet state between the cleaning and the rinsing and between the rinsing and the coating.
